(19) United States
(12) Patent Application Publication
(10) Pub. No.: US 2008/0026517 A1
(43) Pub. Date: Jan. 31, 2008

(54) METHOD FOR FORMING A STRESSOR LAYER

(76) Inventors: Paul A. Grudowski, Austin, TX (US); Kurt H. Junker, Austin, TX (US); Venkat R. Kolagunta, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/460,742

(22) Filed: Jul. 28, 2006

(51) Int. Cl. H01L 21/8234

(52) U.S. Cl. 438/197

(57) ABSTRACT

In one aspect, a method for forming a semiconductor device includes forming a stressor layer over a gate stack and a spacer adjacent the gate stack, implanting a species into at least a portion of the stressor layer, and curing the stressor layer. In another aspect, a method includes forming an etch stop layer over a semiconductor substrate, where the etch stop layer has a structure, modifying at least a portion of the structure of the etch stop layer, and curing the etch stop layer after modifying at least the portion of the structure of the etch stop layer.

### FIELD OF THE INVENTION

This invention relates generally to semiconductor processing, and more specifically, to forming a stressor layer.

### RELATED ART

Stress in the channels in semiconductor devices is currently used to improve device performance. For example, a tensile stress in the channel improves carrier mobility for NMOS (N-type Metal Oxide Semiconductor) devices while a compressive stress in the channel improves carrier mobility for PMOS (P-type Metal Oxide Semiconductor) devices. This tensile or compressive stress can be achieved by applying a stressor layer over the gate and substrate which applies stress to the channel through, for example, the device gate or source/drain regions.

### BRIEF DESCRIPTION OF THE DRAWINGS

The present invention is illustrated by way of example and is not limited by the accompanying figures, in which like references indicate similar elements.

FIGS. 1-6 illustrates formation of a stressor layer, in accordance with one embodiment of the present invention.

FIGS. 7-11 illustrates formation of a stressor layer, in accordance with an alternate embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

Stressor layers may be formed over the gates of semiconductor devices to create a tensile or compressive stress in the channel regions. However, during the formation of a stressor layer, seams may be formed at corners at the base of the sidewall spacer (or gate stack in the case where sidewall spacers are not present), where these seams, during subsequent processing, may cause problems. For example, during subsequent curing, the stressor layer may shrink in volume which may cause these seams to open up, thus relieving desired stress. Also, the opening of the seams may result in higher defectivity and thus lower yield. In one embodiment, an implant is used prior to curing which damages or structurally modifies the stressor layer in order to partially or completely dissolve the seams. In this manner, the seams will be less likely to open or cause problems during the subsequent cure.

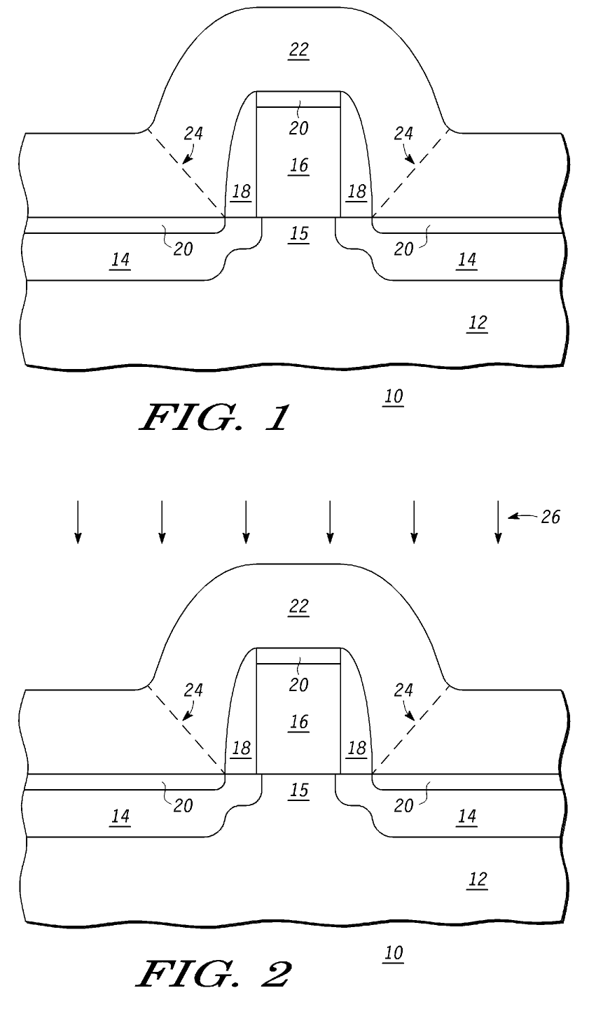

FIG. 1 illustrates a semiconductor device 10 having a semiconductor layer 12, where semiconductor layer 12 may be a bulk substrate or part of a semiconductor on insulator (SOI) substrate. Semiconductor layer 12 can be any semiconductor material or combinations of materials, such as silicon, silicon germanium, gallium arsenide, the like, or combinations thereof. Semiconductor device 10 includes a gate stack 16 which includes a gate dielectric over semiconductor layer 12 and a gate electrode over the gate dielectric. Any suitable material or combination of materials may be used to form gate stack 16. Semiconductor device 10 also includes a sidewall spacer 18 adjacent gate stack 16. Sidewall spacer 18 may be formed using any suitable material or combination of materials. In an alternate embodiment, sidewall spacer 18 may not be present. Semiconductor device 10 includes source/drain regions 14 formed within semiconductor layer 12, and includes a channel region 15 between source/drain regions 14 and under gate stack 16. Semiconductor device 10 also includes silicide regions 20 formed over portions of source/drain regions 14 and gate stack 16, which may allow for improved device contacts. Note that conventional techniques and materials may be used to form source/drain regions 14, channel region 15, gate stack 16, sidewall spacer 18, and silicide regions 20.

Still referring to FIG. 1, semiconductor device 10 includes a stressor layer 22 formed over semiconductor layer 12, sidewall spacer 18, gate stack 16, and silicide regions 20. In one embodiment, stressor layer 22 is a silicon nitride layer which may be formed by plasma enhanced chemical vapor deposition (PECVD). Stressor layer 22 may also include one or more other materials, such as hydrogen, carbon, oxygen, fluorine, the like, or combinations thereof, in addition to silicon and nitride. In one embodiment, stressor layer 22 will also function as an etch stop layer, as will be described below, and may therefore be referred to as an etch stop layer (ESL). In one embodiment, stressor layer 22 has a thickness in a range of approximately 20 to 200 nanometers, and more preferably, in a range of approximately 50 to 100 nanometers. In one embodiment, the PECVD is performed at a deposition temperature in a range of approximately 250 to 500 degrees Celsius, more preferably, in a range of approximately 300 to 400 degrees Celsius, and even more preferably, at a deposition temperature of approximately 300 degrees Celsius. In one embodiment, stressor layer 22 is formed having a stress (e.g. tensile stress) in a range of approximately 200 to 300 MPa.

In one embodiment, the PECVD results in the formation of seams 24 at the corners located at the base of sidewall spacer 18 (or gate stack 16 in the case where sidewall spacer 18 is not present). In one embodiment, seams 24 extend out at an angle of approximately 45 degrees from the area where sidewall spacer 18 meets semiconductor layer 12. In one embodiment, seams 24 represent growth interfaces between two surfaces of stressor layer 22, such as, for example, between the horizontal portion of stressor layer 22 over source/drain regions 14 and vertical portion of stressor layer 22 adjacent sidewall spacer 18. The presence of these growth interfaces may function as stress relieves, which may limit the desired stress being provided by stressor layer 22. In one embodiment, seams 24 may represent voids formed at the growth interfaces. Furthermore, other processing parameters, such as the profile of sidewall spacer 18, any undercutting of a spacer liner (not shown) underneath sidewall spacer 18, etc., may further impact the severity of seams 24.

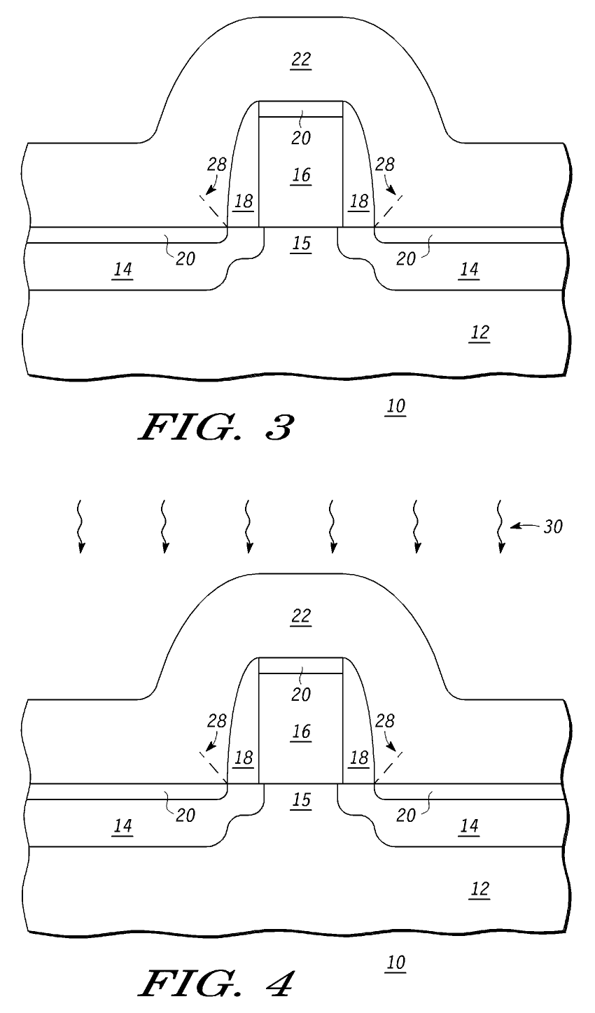

FIG. 2 illustrates performing an implant 26 into at least a portion of stressor layer 22 which structurally modifies at least a portion of stressor layer 22. For example, implant 26 may modify a stress characteristic (e.g. a tensile stress) of stressor layer 22. In one embodiment, implant 26 is performed using a species which structurally modifies at least a portion of stressor layer 22 by breaking chemical bonds and disrupting the as-deposited bonding arrangement within stressor layer 22. In one embodiment, implant 26 is performed using a species such as, for example, xenon, germanium, or silicon. Alternatively, a combination of different implants and different implant species may be used. The energy used to perform implant 26 may be dependent upon the thickness of stressor layer 22. In one embodiment, where xenon is the species, a dose in a range of approximately 1e13 to 100e13/cm² (or more preferably, in a range of approximately 5e13 to 50e13/cm²) at an energy in a range of approximately 50 to 130 keV is used. In one embodiment, implant 26 is performed with an angle of incidence normal to the surface of semiconductor device 10. Alternatively, implant 26 may be performed at other angles, such as, for example, up to approximately 60 degrees from normal to the surface of semiconductor device 10.

FIG. 3 illustrates resulting semiconductor device 10 after implant 26 is performed. In the illustrated embodiment, as a result of implant 26, a portion of seams 24 is removed, leaving remaining seams 28. In one embodiment, portions of seams 24 at the exposed surfaces of stressor layer 22 are dissolved. In one embodiment, substantially all of seams 24 may be dissolved. As discussed above, implant 26 introduces a species which structurally modifies at least a portion of stressor layer 22. In one embodiment, the species rearranges bonds and molecules at seams 24 to erase all or portions of the growth interfaces, i.e. seams 24. Therefore, in one embodiment, implant 26 is used to modify at least a portion of a structure of stressor layer 22 (where the structure of stressor layer 22 may refer to, for example, seams 24). Alternatively, other methods may be used to modify the at least a portion of the structure of the stressor layer 22.

FIG. 4 illustrates performing a cure 30 of stressor layer 22 which may also operate to modify a stress characteristic (e.g. a tensile stress) of stressor layer 22. For example, a tensile stress of stressor layer 22 may be increased. Cure 30 may be any type of thermal or non-thermal cure, such as, for example, electron (e.g. E-beam) and photon (e.g. ultra-violet, flash, or laser anneal) irradiations, or combinations of thermal and non-thermal cures. For example, cure 30 may be a photon irradiation, such as ultra-violet (UV). In one embodiment, the UV cure may be performed at a temperature in range of approximately room temperature (e.g. approximately 25 degrees Celsius) to 500 degrees Celsius, or more preferably, approximately 400 degrees Celsius. In this example, exposure time for cure 30 may be in a range of approximately less than 10 msec up to 60 minutes.

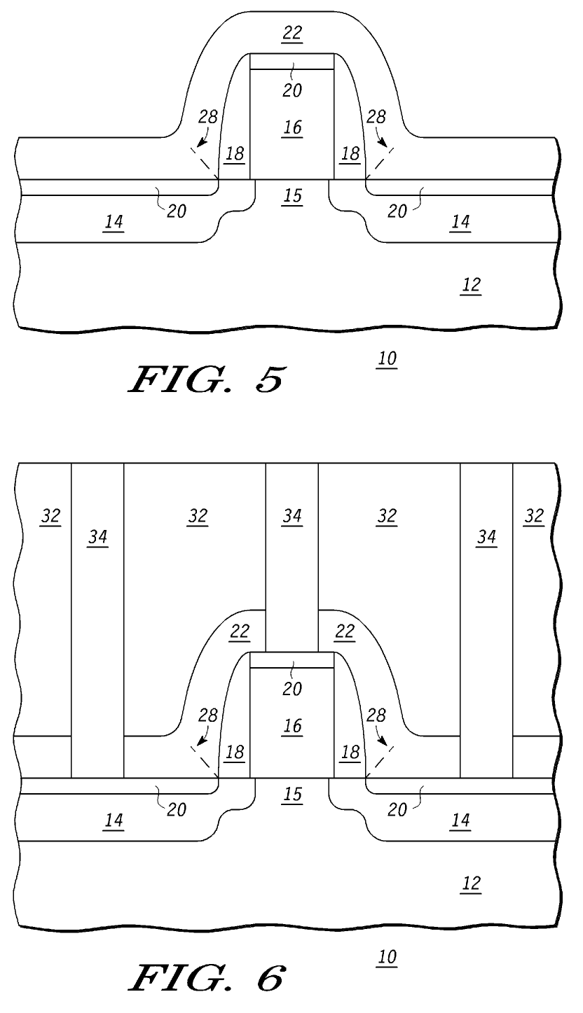

FIG. 5 illustrates semiconductor device 10 after performing cure 30. In one embodiment, cure 30 causes shrinking of stressor layer 22 where a volume of stressor layer 22 is reduced due to removal of materials from stressor layer 22, such as the removal of hydrogen due to a UV cure. Therefore, stressor layer 22 results with a reduced volume, increased density, reduced amount of hydrogen, and higher stress. For example, in one embodiment, the resulting stress (e.g. tensile stress) of stressor layer 22 is at least approximately 1.5 GPa, or in a range of approximately 1.2 to 2.5 GPa. Note that, in the illustrated embodiment, remaining seams 28 do not extend to the surface of reduced stressor layer 22. In this manner, stressor layer 22 may be less prone to cracking during cure 30. The stress in stressor layer 22 is transferred to channel region 15. For example, in one embodiment, a tensile stress created in stressor layer 22 may be transferred to channel region 15 for improved carrier mobility for an NMOS device (where semiconductor device 10 is an NMOS device). In the illustrated embodiment, the stress from stressor layer 22 is transferred through source/drain regions 14 to channel region 15.

FIG. 6 illustrates semiconductor device 10 after formation of interlayer dielectric (ILD) 32 and contacts 34. In one embodiment, ILD 32 is first formed over stressor layer 22, then contact openings are formed in ILD 32 using stressor layer 22 as an etch stop layer. A different etch chemistry may then be used to etch through stressor layer 22 to expose silicide regions 20. A conducive material may then be used fill the contact openings to form contacts 34 to source/drain regions 14 and gate stack 16 (e.g. the gate electrode of gate stack 16). Note that conventional processing and materials may be used to form ILD 32 and contacts 34. Furthermore, subsequent processing may be used to form additional metal layers, as needed, to substantially complete semiconductor device 10.

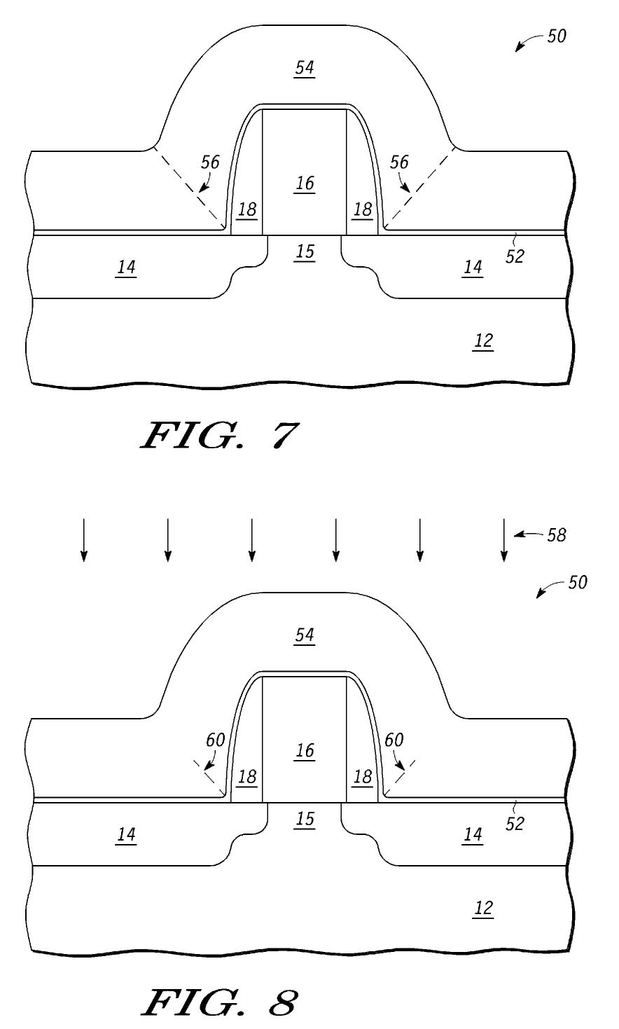

FIGS. 7-11 illustrate an alternate embodiment, in which a stressor layer 54, similar to stressor layer 22, may be formed earlier in the process. In this alternate embodiment, stressor layer 54 is also implanted prior to cure to partially or fully dissolve seams which form during formation of stressor layer 54, as was described above in reference to stressor layer 22. However, stressor layer 54 may be formed earlier in the process and used to apply stress to channel region 15 through gate stack 16. Stressor layer 54 may then be removed prior to subsequent processing.

FIG. 7 illustrates a semiconductor device 50 in which semiconductor layer 12, source/drain regions 14, channel region 15, gate stack 16, and sidewall spacer 18 are as described above in reference to FIG. 1. Semiconductor device 50 includes an etch stop layer 52, which may be an oxide layer, over source/drain regions 14, sidewall spacer 18, and gate stack 16, and stressor layer 54 over etch stop layer 52. Note that conventional processing may be used to form etch stop layer 52. In an alternate embodiment, etch stop layer 52 may not be needed and thus not be present. Note also that the descriptions provided above with respect to the formation of stressor layer 22 also apply to stressor layer 54. Therefore, note that the formation of stressor layer 54 results in seams 56, which are analogous to seams 24 described above.

FIG. 8 illustrates performing an implant 58 into stressor layer 54. Note that implant 58 is analogous to implant 26 and therefore, the descriptions provided above with respect to implant 26 also apply to implant 58. As with implant 26 described above, implant 58 functions to partially or completely dissolve seams 60. In the illustrated embodiment of FIG. 8, seams 58 are partially dissolved, leaving remaining seams 60, which are analogous to remaining seams 28 described above. The descriptions provided above with respect to remaining seams 28 therefore also apply to remaining seams 58.

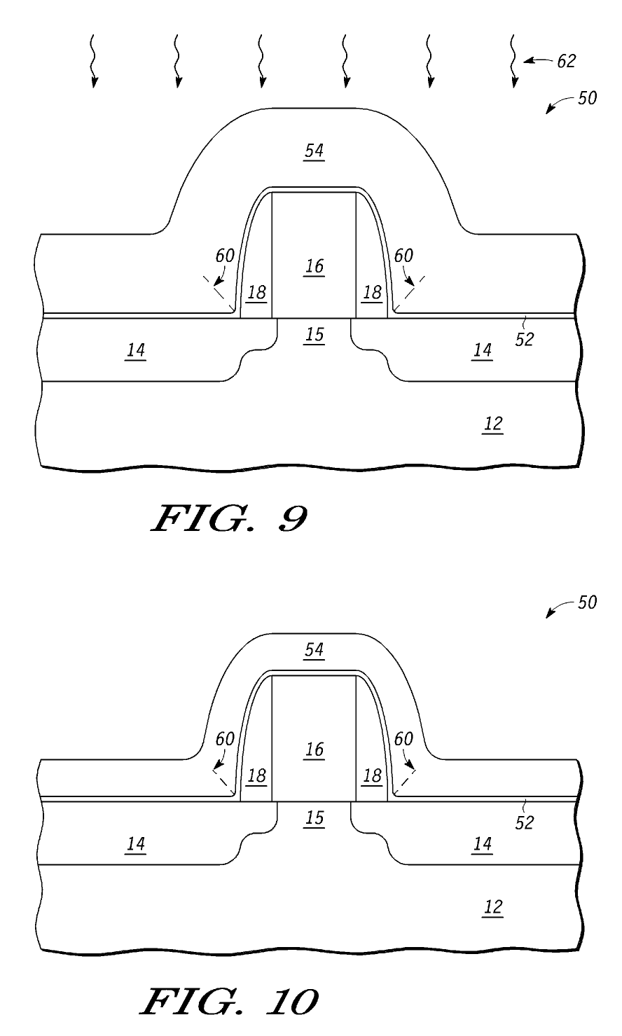

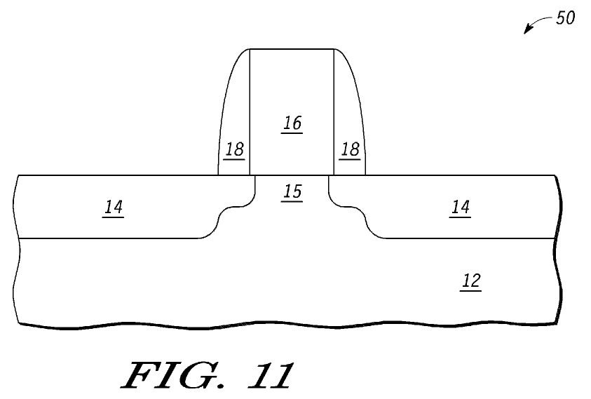

FIG. 9 illustrates performing a cure 62 of stressor layer 54, and FIG. 10 illustrates stressor layer 54 after cure 62, where cure 62 results in a volume reduction of stressor layer 54. Note that cure 62 is analogous to cure 30, and therefore, the descriptions provided above with respect to cure 30 also apply to cure 62. Note that the thickness of layer 54 may be different than layer 22 in the previous embodiment. Note also that the required cure time may increase with increasing thickness of layer 54, and therefore, in one embodiment, may exceed 60 minutes. Note that, in one embodiment, the stress of stressor layer 54 is transferred to channel region 15 through gate stack 16 after a re-crystallization anneal is performed. In one embodiment, cure 62 and the re-crystallization anneal may be combined and performed as a single process.

FIG. 11 illustrates semiconductor device 50 after removal of stressor layer 54 using etch stop layer 52 as an etch stop layer, and then subsequent removal of etch stop layer 52. Note that conventional processing techniques may be used to remove stressor layer 54 and etch stop layer 52.

Processing may then continue to form a substantially completed semiconductor device. In one embodiment, processing may continue using the processing illustrated and described in reference to FIGS. 1-6, where an etch stop stressor layer, such as stressor layer 22, may be subsequently formed in completing semiconductor device 50.

By now it should be appreciated that there has been provided a method for using an implant prior to cure to address the formation of seams in a stressor layer. The implant is performed to partially or completely dissolve the seams, which allows for reduced cracking of the stressor layers during subsequent cures. This may therefore allow for increased stress in the stressor layer, and thus may allow for increased stress in the channel which is transferred from the stressor layer through the source/drain regions or the gate stack. Note also that different implants may be used for different devices within an integrated circuit or across a wafer. In this case, devices can be masked as needed during the implants (such as implants 26 and 58).

Although the invention has been described with respect to specific conductivity types or polarity of potentials, skilled artisans appreciated that conductivity types and polarities of potentials may be reversed.

Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The term “plurality”, as used herein, is defined as two or more than two. The term another, as used herein, is defined as at least a second or more.

Because the above detailed description is exemplary, when “one embodiment” is described, it is an exemplary embodiment. Accordingly, the use of the word “one” in this context is not intended to indicate that one and only one embodiment may have a described feature. Rather, many other embodiments may, and often do, have the described feature of the exemplary “one embodiment.” Thus, as used above, when the invention is described in the context of one embodiment, that one embodiment is one of many possible embodiments of the invention.

Notwithstanding the above caveat regarding the use of the words “one embodiment” in the detailed description, it will be understood by those within the art that if a specific number of an introduced claim element is intended in the below claims, such an intent will be explicitly recited in the claim, and in the absence of such recitation no such limitation is present or intended. For example, in the claims below, when a claim element is described as having “one” feature, it is intended that the element be limited to one and only one of the feature described.

Furthermore, the terms “a” or “an”, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

What is claimed is:

1. A method of forming a semiconductor device, the method comprising:
forming a stressor layer over a gate stack and a spacer adjacent the gate stack;
implanting a species into at least a portion of the stressor layer; and
curing the stressor layer.

2. The method of claim 1, wherein curing the stressor layer comprises modifying a stress of the stressor layer.

3. The method of claim 2, wherein implanting the species into at least the portion of the stressor layer comprises modifying the stress of the stressor layer.

4. The method of claim 2, wherein modifying the stress of the stressor layer comprises increasing the tensile strength of the stressor layer.

5. The method of claim 4, wherein modifying the stress of the stressor layer comprises forming the stressor layer having a stress of approximately 1.5 GPa or greater.

6. The method of claim 1, wherein forming the stressor layer comprises forming a layer comprising silicon and nitrogen.

7. The method of claim 6, wherein forming the stressor layer further comprises depositing the stressor layer at a temperature of approximately 300 degrees Celsius.

8. The method of claim 1, further comprising removing the stressor layer after curing the stressor layer.

9. The method of claim 1, wherein implanting the species into at least the portion of the stressor layer comprises implanting a species selected from the group consisting of xenon, germanium, and silicon.

10. The method of claim 9, wherein implanting the species into at least the portion of the stressor layer comprises implanting the species using an energy of approximately 50 to approximately 130 KeV.

11. The method of claim 1, wherein curing the stressor layer comprises shrinking a volume of the stressor layer.

12. The method of claim 1, wherein forming the stressor layer over the gate stack and the spacer adjacent the gate stack comprises forming an etch stop layer over the gate stack and the spacer.

13. The method of claim 1, wherein curing the stressor layer comprises a cure selected from the group consisting of thermal, E-beam, laser, and ultra-violet irradiation.

14. A method of forming a semiconductor device, the method comprising:
forming an etch stop layer over a semiconductor substrate, wherein the etch stop layer has a structure;
modifying at least a portion of the structure of the etch stop layer; and
curing the etch stop layer after modifying at least the portion of the structure of the etch stop layer.

15. The method of claim 14, wherein modifying at least the portion of the structure of the etch stop layer comprises removing at least a portion of a seam within the etch stop layer.

16. The method of claim 14, wherein modifying at least the portion of the structure of the etch stop layer comprises implanting a species into at least the portion of the stressor layer, wherein the species is selected from the group consisting of xenon, germanium, and silicon.

17. The method of claim 14, wherein modifying at least the portion of the structure of the etch stop layer and curing the stressor layer comprises modifying a tensile stress of the etch stop layer.

18. A method of forming a semiconductor device, the method comprising:
depositing a stressor layer over a semiconductor layer at a temperature less than approximately 400 degrees Celsius, wherein the stressor layer has a first tensile stress;
modifying a stress characteristic of at least a portion of the stressor layer from the first tensile stress to a second tensile stress, wherein modifying comprises:
implanting a species into at least a portion of the stressor layer; and
curing the stressor layer after implanting the species.

19. The method of claim 18, wherein:
depositing the stressor layer comprises depositing a layer comprising silicon and nitrogen;
implanting the species comprises implanting the species selected from the group consisting of xenon, germanium, and silicon; and
curing the stressor layer comprises a cure selected from the group consisting of thermal, E-beam, laser, irradiation, and ultra-violet.

20. The method of claim 18, further comprising removing the stressor layer after modifying the stress characteristic.
